(19) United States
(12) Patent Application Publication
(10) Pub. No.: US 2023/0255033 A1
(43) Pub. Date: Aug. 10, 2023

(54) FERROELECTRIC MEMORY DEVICE

(71) Applicant: Japan Science and Technology Agency, Kawaguchi-shi (JP)

(72) Inventors: Masaharu Kobayashi, Tokyo (JP); Fei Mo, Tokyo (JP); Toshiro Hiramoto, Tokyo (JP)

(21) Appl. No.: 18/300,728

(22) Filed: Apr. 14, 2023

Related U.S. Application Data
(63) Continuation of application No. PCT/JP2021/043742, filed on Nov. 30, 2021.

(30) Foreign Application Priority Data
Dec. 4, 2020 (JP) 2020-202180

(51) Int. Cl. H10B 51/20; H10B 51/30

(52) U.S. Cl. CPC H10B 51/20; H10B 51/30

(57) ABSTRACT

A ferroelectric memory device has a three-dimensional stacked structure with multiple ferroelectric memory elements arranged in series. The ferroelectric memory device has a semiconductor member having a columnar shape including a metal oxide, a ferroelectric layer containing hafnium oxide and surrounding the semiconductor member in contact with a side surface of the semiconductor member, and a plurality of gate electrodes arranged along a longitudinal direction of the semiconductor member and facing a side surface of the semiconductor member through the ferroelectric layer. The semiconductor member is a continuous member from its outer periphery to its central axis.

### CROSS REFERENCE TO RELATED APPLICATIONS

This application is a Continuation of International Patent Application No. PCT/JP2021/043742, filed on Nov. 30, 2021, which claims the benefit of priority to Japanese Patent Application No. 2020-202180, filed on Dec. 4, 2020, the entire contents of which are incorporated herein by reference.

### FIELD

An embodiment of the present invention relates to a non-volatile memory device. Particularly, the present invention relates to a non-volatile memory device having a three-dimensional stacked structure in which a plurality of non-volatile memory elements is arranged in series.

### BACKGROUND

In recent years, with the sophistication of semiconductor systems, information communication is required in various situations of daily life. Implementation of so-called IoT (Internet of Things) requires high speed and large capacity communication between computers (for example, servers) and Internet-connected products (also referred to as edge devices). For this purpose, a non-volatile memory as a high speed and large capacity storage memory is required for an Internet-connected product. Furthermore, with the miniaturization of Internet-connected products, non-volatile memories are strongly required to have low power consumption.

With the growing demand for non-volatile memories, ferroelectric memories, which have been known for a long time, are attracting new spotlight. For example, ferroelectric memories using hafnium oxide-based materials are characterized by high compatibility with CMOS processing, high erase/program speeds, low voltage operation, and low power consumption. Therefore, recently, a FeFET (Ferroelectric Field Effect Transistor) using hafnium oxide-based materials as a gate insulating layer has been actively developed (for example, Min-Kyu Kim, Jang-Sik Lee, “Ferroelectric Analog Synaptic Transistors”, [online], Jan. 30, 2019, American Chemical Society, [Search on Feb. 13, 2019], Internet <URL:https://pubs.acs.org/doi/abs/10.1021/acs.nanolett.9b0018 0> (2019), and Yuxing Li, Renrong Liang, Jiabin Wang, Ying Zhang, He Tian, Houfang Liu, Songlin Li, Weiquan Mao, Yu Pang, Yutao Li, Yi Yang, Tian-Ling Ren, “A Ferroelectric Thin Film Transistor Based on Annealing-Free HfZrO Film”, Jul. 26, 2017, IEEE Journal of the Electron Devices Society, Volume 5, Page(s): 378-383, (2017).) In addition, in order to further increase the capacity of the storage memory, a high density and low power consumption memory in which a plurality of FeFET is integrated in a three-dimensional structure has been proposed (for example, K. Florent, M. Pesic, A. Subirats, K. Banerjee, S. Lavizzari, A. Arreghini, L. Di Piazza, G. Potoms, F. Sebaai, S. R. C. McMitchell, M. Popovici, G. Groeseneken, J. Van Houdt, “Vertical Ferroelectric HfO₂ FET based on 3-D NAND Architecture: Towards Dense Low-Power Memory”, 2018 IEEE International Electron Devices Meeting (IEDM), Page(s): 2.5.1-2.5.4, (2018), and Jun. 9, 2019, IEEE, 2019 Symposium on VLSI Technology Digest of Technical Papers, T42-43, (2019).) Particularly, the memory having the three-dimensional stacked structure described in 2019 Symposium on VLSI Technology Digest of Technical Papers uses a hafnium oxide-based material as a gate insulating film, and uses a semiconductor material (for example, IGZO) containing a metal oxide as a channel layer.

### SUMMARY

A ferroelectric memory device according to an embodiment of the present invention has a three-dimensional stacked structure with multiple ferroelectric memory elements arranged in series. The ferroelectric memory device has a semiconductor member having a columnar shape including a metal oxide, a ferroelectric layer containing hafnium oxide and surrounding the semiconductor member in contact with a side surface of the semiconductor member, and a plurality of gate electrodes arranged along a longitudinal direction of the semiconductor member and facing a side surface of the semiconductor member through the ferroelectric layer. The semiconductor member is a continuous member from an outer periphery to a central axis. Here, “C facing B via A” is a relationship that should be satisfied by at least a part of A, at least a part of B, and at least a part of C, and is not limited to a relationship that should be satisfied by all of A, all of B, or all of C.

In the ferroelectric memory device, the multiple ferroelectric memory elements may share the same semiconductor member. A diameter of the semiconductor member may be 20 nm or less. The metal oxide may be preferably a first oxide comprising one or more metals selected from a group consisting of In, Ga, Zn, and Sn. For example, the metal oxide may be IGZO (a metal oxide composed of indium, gallium, zinc, and oxygen), ITO (Indium Tin Oxide), IZO (Indium Zinc Oxide), ITZO (Indium Tin Zinc Oxide), ZnO (Zinc Oxide), or InO (Indium Oxide). The metal oxide may be preferably a second oxide comprising a plurality of metals selected from a group consisting of In, Al, and Zn. For example, the second oxide may be IAO (Indium Aluminum Oxide) or IAZO (Indium Aluminum Zinc Oxide). The metal oxide may be preferably a third oxide consisting of In and element X (Si, Hf, Zr, Ti, Ta, W), or the first oxide or the second oxide plus at least one of element X.

The ferroelectric memory device may further comprise a plurality of insulating layers provided between each of the plurality of gate electrodes.

In the ferroelectric memory device, a width of each of the plurality of gate electrodes is 1 μm or less.

In the ferroelectric memory device, a thickness of the ferroelectric layer may be 5 nm or more and 22 nm or less.

### BRIEF DESCRIPTION OF THE DRAWINGS

FIG. 1 is a cross-sectional view showing an element structure in a non-volatile memory device according to an embodiment of the present invention.

FIG. 2 is a cross-sectional perspective view showing an element structure in a non-volatile memory device according to an embodiment of the present invention.

FIG. 3 is a perspective view showing a configuration of a semiconductor member and a gate insulating layer in the non-volatile memory element shown in FIG. 2.

FIG. 4 is a graph showing Id-Vg characteristics of a non-volatile memory device according to an embodiment of the present invention.

FIG. 5 is a graph plotting the width of a memory window and a channel length obtained from the Id-Vg characteristics of FIG. 4.

FIG. 6 is a graph showing relationships between an SS value and a drain current obtained from the Id-Vg characteristics of FIG. 4.

FIG. 7 is a diagram showing a distribution of a polarization charge of a gate insulating layer in a non-volatile memory device according to an embodiment of the present invention.

FIG. 8 is a diagram showing a distribution of a polarization charge of a gate insulating layer in a non-volatile memory element of a comparative example 1.

FIG. 9 is a diagram showing a simulation model of an electric field distribution inside a gate insulating layer in a non-volatile memory element according to an embodiment of the present invention.

FIG. 10 is a diagram showing a simulation result of an electric field distribution inside a gate insulating layer in a non-volatile memory element according to an embodiment of the present invention.

FIG. 11 is a graph showing Id-Vg characteristics of a non-volatile memory device according to an embodiment of the present disclosure.

FIG. 12 is a graph showing a relationship between a width of a memory window and a diameter of channels obtained from the Id-Vg characteristics shown in FIG. 11.

FIG. 13 is a graph showing relationships between an SS value and a drain current obtained from the Id-Vg characteristics shown in FIG. 11.

FIG. 14 is a cross-sectional perspective view showing an element structure in a non-volatile memory element of a comparative example 2.

FIG. 15 is a graph showing Id-Vg characteristics of the non-volatile memory device of the comparative example 2.

FIG. 16 is a graph showing a relationship between a width of a memory window and a channel length obtained from the Id-Vg characteristics shown in FIG. 15.

FIG. 17 is a graph showing relationships between an SS value and a drain current obtained from the Id-Vg characteristics shown in FIG. 15.

FIG. 18 is a graph comparing a dependence of a width of a memory window on a channel length in a non-volatile memory element of an embodiment of the present invention and that of the comparative example 2.

FIG. 19 is a cross-sectional perspective view showing a modification of an element structure in a non-volatile memory device according to an embodiment of the present invention.

FIG. 20 is a graph showing a relationship between a width of a memory window and a film thickness of a gate insulating layer 220 in a non-volatile memory element of the element structure shown in FIG. 19.

FIG. 21 is a cross-sectional perspective view showing a modification of an element structure in a non-volatile memory device according to an embodiment of the present invention.

FIG. 22 is a graph showing a relationship between a width of a memory window and a film thickness of a semiconductor member in a non-volatile memory element of the element structure shown in FIG. 21.

FIG. 23 is a cross-sectional perspective view corresponding to the element structure of the non-volatile memory element of the comparative example 2.

### DESCRIPTION OF EMBODIMENTS

As described above, in recent years, by integrating non-volatile memories (for example, ferroelectric memories) at high density, memories having a three-dimensional stacked structure with low power consumption and high reliability are being realized. However, it is expected that the miniaturization of Internet-connected products will rapidly proceed in the future. Therefore, there is a demand for development of a non-volatile memory that can operate with lower power consumption without impairing reliability.

An object of the present invention is to provide a highly reliable non-volatile memory device. Particularly, an object of the present invention is to provide a non-volatile memory device with low power consumption and high reliability.

Hereinafter, embodiments of the present invention will be described with reference to the drawings and the like. However, the present invention can be implemented in various aspects without departing from the gist thereof, and the present invention is not to be construed as being limited to the description of the embodiments exemplified below. In the drawings, widths, thicknesses, shapes, and the like of respective portions may be schematically represented in comparison with the actual embodiments for clarity of explanation, but the drawings are merely examples, and do not limit the interpretation of the present invention. In the present specification and the drawings, elements having the same functions as those described with respect to the drawings described above are denoted by the same reference numerals, and redundant descriptions thereof may be omitted.

In the embodiments described below, temperature conditions of simulations are both at room temperature.

### Element Structure

Hereinafter, a non-volatile memory device 100 according to an embodiment of the present invention will be described.

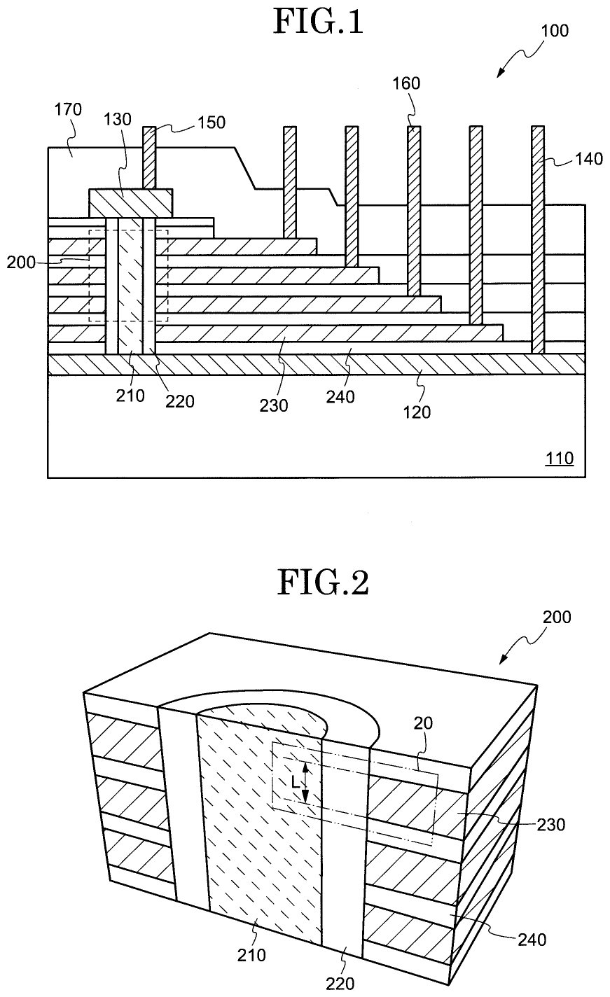

FIG. 1 is a cross-sectional view showing an element structure of the non-volatile memory device 100 according to an embodiment of the present invention. The non-volatile memory device 100 shown in FIG. 1 has a three-dimensional stacked structure in which a plurality of non-volatile memory elements 20 (see FIG. 2) is three-dimensionally integrated. The plurality of non-volatile memory elements 20 is arranged in series along a longitudinal direction of a semiconductor member 210 in common with the columnar semiconductor member 210 functioning as a channel. In the present embodiment, the non-volatile memory element 20 is a FeFET (Ferroelectric Field Effect Transistor) having a gate insulating layer made of ferroelectric.

A source electrode 120 is provided on a substrate 110. As the substrate 110, a silicon substrate having an insulating surface, a metal substrate, or the like can be used. As the source electrode 120, a metal material containing titanium, aluminum, tungsten, tantalum, molybdenum, copper, or the like, or a compound material containing these metal materials can be used. In the case where an n-type semiconductor substrate (for example, an n-type silicon substrate) is used as the substrate 110 to function as a source, the source electrode 120 shown in FIG. 1 can be omitted.

The plurality of non-volatile memory elements 20 is arranged in series between the source electrode 120 and a drain electrode 130. The semiconductor member 210 is electrically connected to the source electrode 120 and the drain electrode 130. That is, in the non-volatile memory device 100, the plurality of non-volatile memory elements 20 shares the source electrode 120 and the drain electrode 130 in addition to the semiconductor member 210.

The source electrode 120 is electrically connected to a source terminal 140 made of a metal material. The drain electrode 130 is electrically connected to a drain terminal 150 made of a metal material. The drain terminal 150 is connected to a bit line (not shown) of the non-volatile memory device 100. A plurality of gate electrodes 230 is electrically connected to gate terminals 160, respectively. The plurality of gate terminals 160 is connected to a word line (not shown) of the non-volatile memory device 100. The source terminal 140, the drain terminal 150, and the gate terminal 160 are electrically connected to the source electrode 120, the drain electrode 130, and the gate electrode 230, respectively, via contact holes provided in a passivation layer 170, insulating layers 240 provided between each of the gate electrodes 230, and an insulating layer 240 provided between the lowest gate electrode 230 and the source electrode 120.

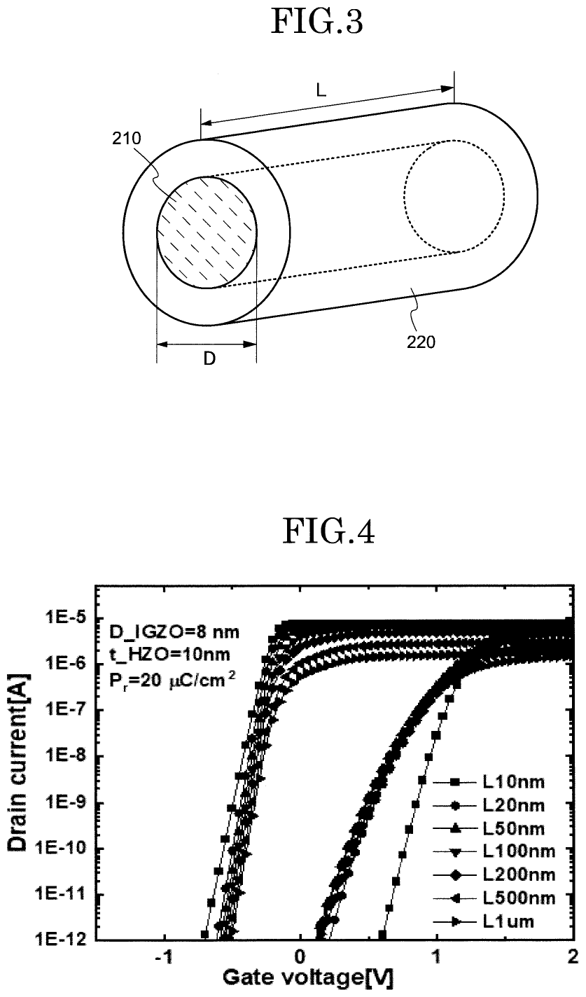

FIG. 2 is a cross-sectional perspective view showing an element structure in the non-volatile memory device 100 according to an embodiment of the present invention. Specifically, FIG. 2 is an enlarged view of a portion surrounded by a grid line 200 in the non-volatile memory device 100 shown in FIG. 1 (a portion corresponding to the three non-volatile storage elements 20). FIG. 3 is a perspective view showing a configuration of the semiconductor member 210 and a gate insulating layer 220 in the non-volatile memory element 20 shown in FIG. 2.

As shown in FIG. 2, the non-volatile memory element 20 of the present embodiment is a FeFET including the semiconductor member 210, the gate insulating layer 220, and the gate electrode 230. In the non-volatile memory device 100 of the present embodiment, the plurality of non-volatile memory elements 20 shares the semiconductor member 210 and the gate insulating layer 220.

The semiconductor member 210 is a columnar member that functions as a channel of the non-volatile memory element 20. As shown in FIG. 2 and FIG. 3, the semiconductor member 210 has substantially no hollow portion or other member therein. Here, “substantially no hollow portion or other member therein” means, for example, that minute hollow portions or other members may be included in the semiconductor member 210. That is, minute hollow portions or other members that do not significantly affect the element characteristics may be present in the semiconductor member 210. The semiconductor member 210 is a continuous member extending from an outer peripheral surface to a central axis. That is, the semiconductor member 210 is made of the same material (including a material that can be regarded as substantially the same) continuously from the outer peripheral surface to the central axis.

In the present embodiment, a metal oxide called IGZO is used as a component of the semiconductor member 210. IGZO is a metal oxide that exhibits semiconductor properties, and a compound composed of indium, gallium, zinc, and oxygen. Particularly, IGZO is an oxide comprising In, Ga and Zn or mixtures of such oxides. IGZO is preferably In₂₋ₓGaₓO₃(ZnO)ₘ (0<x<2, where m is a natural number 0 or less than 6), more preferably InGaO₃(ZnO)ₘ (where m is a natural number 0 or less than 6), and most preferably InGaO₃(ZnO).

In the present embodiment, the semiconductor member 210 has a cylindrical shape. However, the present invention is not limited to this example, and the semiconductor member 210 may be an elliptical columnar or prismatic member. In the present embodiment, a diameter (D) of the semiconductor member 210 is 8 nm. The diameter of the semiconductor member 210 may be set to, for example, 30 nm or less (preferably 1 nm or more and 20 nm or less, more preferably 4 nm or more and 10 nm or less). In the case where the semiconductor member 210 has a shape other than the cylindrical shape, the diameter or length of the semiconductor member 210 in a direction substantially orthogonal to an interface between the semiconductor member 210 and the gate insulating layer 220 may be regarded as the diameter of the semiconductor member 210 and set.

As shown in FIG. 1 and FIG. 2, in the present embodiment, a cylindrical semiconductor member 210 having a longitudinal direction in a direction substantially orthogonal to the substrate 110 is used. In this case, when the non-volatile memory device 100 is manufactured, for example, holes having a diameter of 30 nm or less is filled with the metal oxide material to form the semiconductor member 210. In the present embodiment, the semiconductor member 210 is formed using an ALD (Atomic Layer Deposition) method. However, the present invention is not limited thereto, and the semiconductor member 210 may be formed using a PLD (Pulsed Laser Deposition) method, a DC sputtering method, a RF sputtering method, a spin coating method, a dip coating method, a mist CVD (Mist Chemical Vapor Deposition) method, or the like. Particularly, a solution-based method such as a spin coating method is suitable for filling the holes with the metal oxide material.

The gate insulating layer 220 corresponds to a ferroelectric layer in the non-volatile memory element 20 of the present embodiment. In the present embodiment, hafnium oxide to which zirconium is added (hereinafter referred to as “HZO”) is used as a ferroelectric material constituting the gate insulating layer 220. However, the present invention is not limited thereto, and other ferroelectric layers such as hafnium oxide to which silicon, aluminum, gadolinium, yttrium, lanthanum, strontium, and the like are added may also be used as the gate insulating layer 220. In the present embodiment, the gate insulating layers 220 are formed using ALD (Atomic Layer Deposition) method with a film thickness of 10 nm. However, the thickness of the gate insulating layer 220 is not limited to this example, and may be, for example, 5 nm or more and 22 nm or less (preferably, 10 nm or more and 18 nm or less).

The gate insulating layer 220 is provided so as to surround the semiconductor member 210 in contact with the side surface of the semiconductor member 210. That is, as shown in FIG. 3, the gate insulating layer 220 can be said to be a cylindrical member having a cylindrical semiconductor member 210 having the diameter (D) inside. As described above, the channel portion of the present embodiment has a structure in which a space inside the cylindrical gate insulating layer 220 is occupied by the semiconductor member 210.

The gate electrode 230 functions as a gate for controlling a program operation or an erase operation of the non-volatile memory element 20. In the present embodiment, a compound layer made of titanium nitride (TiN) is used as the gate electrode 230. However, the material of the gate electrode 230 is not limited thereto, and a metal material containing tungsten, tantalum, molybdenum, aluminum, copper, or the like, or a compound material containing these metal materials can be used. The gate electrode 230 can be formed by, for example, the sputtering method.

For the formation of the gate electrode 230, a technique called a gate first method or a gate last method can be used. In the gate first method, first, a step of forming a stack structure by alternately stacking polysilicon layers and insulating layers such as silicon oxide on a substrate, and a step of forming a plurality of holes in a direction perpendicular to the stack structure to form a ferroelectric layer and a channel layer inside the plurality of holes (punch-and-plug). The polysilicon layer formed on the substrate is used as a gate electrode (polysilicon gate) as it is. In the gate last method, first, dummy layers made of silicon nitride or the like and insulating layers made of silicon oxide or the like are alternately stacked to form a stack structure, and the punch-and-plug process described above is performed. Thereafter, a step of selectively removing the dummy layers and a step of embedding a metal material such as tungsten in spaces formed by the removal of the dummy layers are performed, and metal layers made of the embedded metal material is used as gate electrodes (metal gates). Here, lithography and reactive ion etching can be used to form the holes. In addition, the CVD method or the ALD method can be used for embedding the spaces. The gate last method has an advantage that a device having a metal gate having a lower resistance than the polysilicon gate can be manufactured, while the process is complicated.

In the non-volatile memory element 20 of the present embodiment, a width (thickness) of the gate electrode 230 corresponds to a channel length (L) of the non-volatile memory element 20. The width of the gate electrode 230 is a thickness of a titanium nitride layer functioning as the gate electrode 230. In the present embodiment, the gate electrode 230 has a length of 1 μm or less (preferably, 50 nm or less). As will be described later, the non-volatile memory element 20 of the present embodiment can secure a stable memory window in the case where the channel length is 1 μm or less.

The insulating layer 240 is an insulating film for insulating and separating two gate electrodes 230 adjacent to each other. As the insulating layer 240, an insulating film such as a silicon oxide film or a silicon nitride film can be used. In the present embodiment, a thickness of the insulating layer 240 is 10 nm or more and 50 nm or less (preferably 20 nm or more and 40 nm or less), but is not limited to this example. The thickness of the insulating layer 240 may be appropriately determined according to a relationship with the channel length (that is, the width of the gate electrode 230). However, if the thickness of the insulating layer 240 is too thin, the adjacent non-volatile memory elements 20 may have an influence on each other, which may cause an operation failure. In addition, if the thickness of the insulating layer 240 is too thick, the distance between channels of the adjacent non-volatile memory elements 20 becomes long, which may serve as a barrier for carrier movement.

As described above, the non-volatile memory device 100 of the present embodiment has a three-dimensional stacked structure in which the plurality of non-volatile memory elements 20 is integrated at a high density. In addition, since each non-volatile memory element 20 uses the metal oxide called IGZO as channels, they are highly reliable. IGZO has fewer inner defects than polysilicon, which is generally used as FET channels, and is less likely to cause a decrease in carrier mobility. Further, since IGZO does not form an interface layer (low-k layer) having a lower dielectric constant at an interface with the ferroelectric layer, it is possible to reduce a voltage drop generated when the voltage is supplied to the gate electrode. The fact that low quality low-k layers are not generated means that degradation of element properties due to charge trapping or the like can also be reduced. In addition to these benefits, IGZO has adequate carrier mobility in the deposited state (for example, amorphous state), so that it does not need to be polycrystalline by an annealing process, and is not affected by grain boundaries and crystal defects. In addition, non-volatile memory elements using IGZO as channels can operate as junction-less FET (transistors without pn junctions). Therefore, in FET which uses IGZO as a channel, carriers move in the channel body (near the center of the channel) and are less susceptible to charge trapping in the vicinity of the interface layers.

For the above reasons, the non-volatile memory element 20 of the present embodiment can realize high reliability by using IGZO as channels. Further, as will be described later, the non-volatile memory device 100 of the present embodiment can operate with low power consumption by the individual non-volatile memory elements 20. Therefore, according to the present embodiment, it is possible to obtain the non-volatile memory device 100 having the large capacity, low power consumption, and high reliability. Hereinafter, the element characteristics of the non-volatile memory element 20 will be described with reference to simulation results.

### [Element Characteristics]

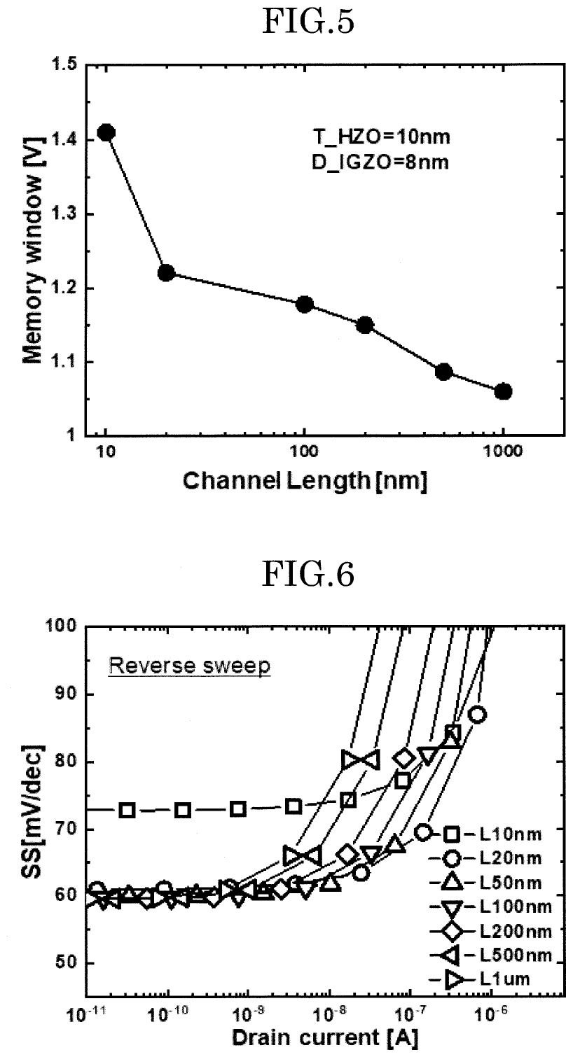

FIG. 4 is a graph showing a result of simulated Id-Vg characteristics of the non-volatile memory element 20 according to an embodiment of the present invention. Specifically, FIG. 4 shows a dependence of the Id-Vg characteristics on the channel length in FeFET having the configurations shown in FIG. 2 and FIG. 3. FIG. 5 is a graph showing a relationship between a width of a memory window and the channel length obtained from the Id-Vg characteristics of FIG. 4. FIG. 6 is a graph showing relationships between an SS value and a drain current obtained from the Id-Vg characteristics of FIG. 4.

In the Id-Vg characteristics shown in FIG. 4, a channel length (L) of the semiconductor member 210 was set to be 10 nm, 20 nm, 50 nm, 100 nm, 200 nm, 500 nm or 1 μm, respectively. In FIG. 4, diameters of the semiconductor member 210 and thicknesses of the gate insulating layers 220 were set to 8 nm and 10 nm, respectively. Residual polarization (Pr) was set at 20 μC/cm². A source-drain voltage (Vds) was set to 50 mV, and a source-gate voltage (hereinafter referred to as “gate voltage”) (Vg) was swept from −5 V to 5 V.

According to the simulation results shown in FIG. 4, the memory window having a sufficient width is obtained in a range in which the channel length is 1 μm or less regardless of the length of the channel. Particularly, in a range in which the channel length is 20 nm or more and 1 μm or less, almost the same stable Id-Vg characteristics are obtained, and there is no significant change in the width of the memory window. That is, from the simulation result shown in FIG. 4, it was found that the non-volatile storage element 20 of the present embodiment has enough memory windows and there is almost no change in the width of the memory windows as long as the channel length is 20 nm or more and 1 μm or less.

In this regard, as shown in FIG. 5, in the case where the channel length is in the range of 20 nm or more and 1 μm or less, the width of the memory window is stable in the range of 1.0 V or more and 1.3 V or less (specifically, 1.05 V or more and 1.25 V or less). In other words, in a range in which the channel length is 20 nm or more and 1 μm or less, the width of the memory window falls within the range of 1.15 V±0.1 V. As described above, the non-volatile memory element 20 according to the present embodiment can secure a stable memory window width without depending on the channel length in a range in which the channel length is 20 nm or more and 1 μm or less.

On the other hand, as shown in FIG. 4, in the case where the channel length is 10 nm, a memory window having a larger width than other channel lengths is obtained. Specifically, as shown in FIG. 5, in the case where the channel length is 10 nm, the width of the memory window is about 1.4 V. This factor is considered to be the influence of the coupling between a source-side potential and a drain-side potential in the gate insulating layer 220.

Further, as shown in FIG. 6, in the case where the channel length is 20 nm or more and 1 μm or less, an SS value of about 60 mV/dec close to the idealized value is obtained. In other words, it has been found that the non-volatile memory element 20 can realize a stable memory window width in a range of a channel length of 20 nm or more and 1 μm or less, and exhibits excellent cut-off properties. On the other hand, in the case where the channel length is 10 nm, a slight degradation in the SS value is confirmed. In view of the above, it is considered that, in the non-volatile memory element 20 of the present embodiment, in the case where the channel length is less than 20 nm, a property degradation such as a so-called short channel effect occurs due to an effect of coupling between the source-side potential and the drain-side potential.

Further, as shown in FIG. 4, in the non-volatile memory element 20 of the present embodiment, a good switching operation is obtained at a low voltage of ±1.0 V or less regardless of the channel length in a range of a channel length of 1 μm or less. Particularly, in the case where the channel length is 20 nm more and 1 μm or less, a good switching operation is obtained at a low voltage of ±0.5 V or less. As described above, the non-volatile memory element 20 of the present embodiment is capable of operating at a low voltage, and thus has a feature of low power consumption.

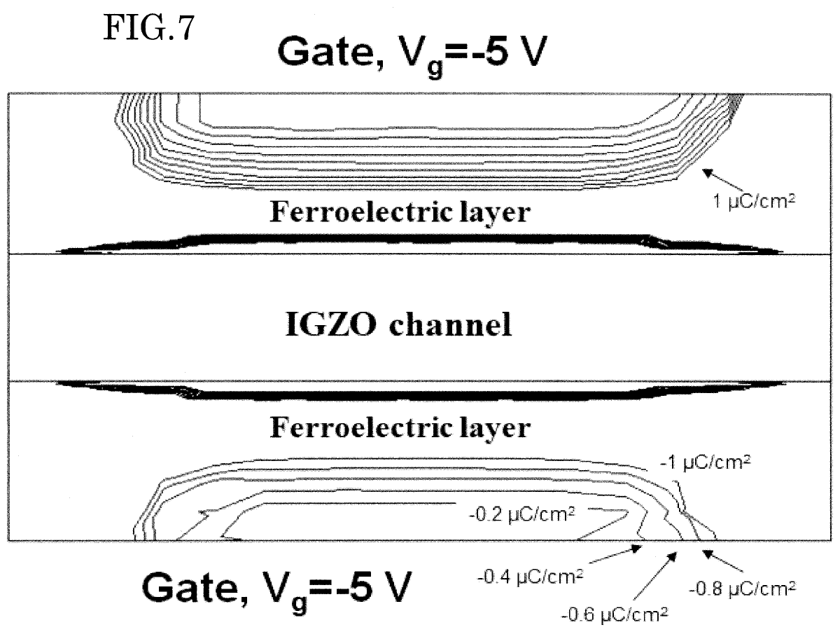

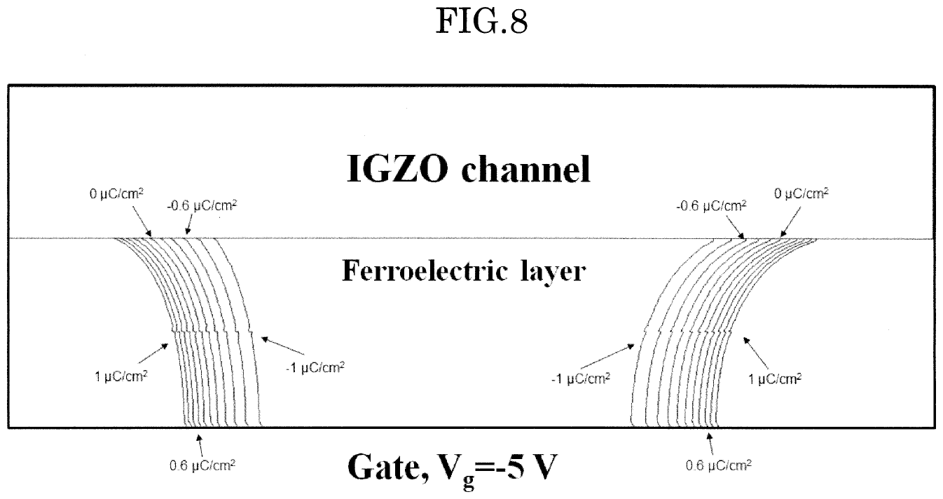

Next, FIG. 7 is a diagram showing a distribution of a polarization charge of the gate insulating layer 220 in the non-volatile memory element 20 according to the embodiment of the present invention. FIG. 8 is a diagram showing a distribution of a polarization charge of the gate insulating layer 220 in the non-volatile memory element of the comparative example 1. In the simulations shown in FIG. 7 and FIG. 8, the gate voltages are set to −5 V. The gate insulating layers (ferroelectric layers) are set as a continuous body model. FIG. 7 and FIG. 8 show dielectric polarization moments of the gate insulating layers in the case where the channel length is 50 nm at 0.2 μC/cm² steps. In FIG. 7 and FIG. 8, a length of a long side of a rectangle described as “IGZO Channel” representing a channel corresponds to a channel length.

As shown in FIG. 7, the gate insulating layers 220 (areas marked as “Ferroelectric layer”) in the non-volatile memory element 20 are continuously reversed in spontaneous polarization along the channels. That is, the spontaneous polarization of the gate insulating layer 220 in the non-volatile memory element 20 is continuously reversed from the source to the drain. In FIG. 7, the sign (±) of the spontaneous polarization is reversed between an upper side and a lower side of the channel, which means that the vector direction of the electric field is reversed. In addition, a portion where spontaneous polarization inversion does not occur at a position away from the channel is observed, which is considered to be caused by treating the ferroelectric layer as a continuous body model.

As described above, since the gate insulating layer 220 of the non-volatile memory element 20 continuously reverses the spontaneous polarization from the source side to the drain side, it is possible to control a good write operation (the program operation and the erase operation).

On the other hand, FIG. 8 shows a simulation result of a planar structure FeFET in which IGZO is used as channel and a ferroelectric layer is used as a gate insulating layer. In this case, although the inversion of the spontaneous polarization of the gate insulating layer is observed on a left side and a right side, it is not observed near the center. That is, in the gate insulating layer in the non-volatile memory element of the comparative example 1, the inversion of the spontaneous polarization occurs in a vicinity of the source and in a vicinity of the drain, but the inversion of the spontaneous polarization does not occur in a portion far from the source and the drain.

The reason why the inversion of the spontaneous polarization as shown in FIG. 7 is observed in the non-volatile memory element 20 of the present embodiment will be described below.

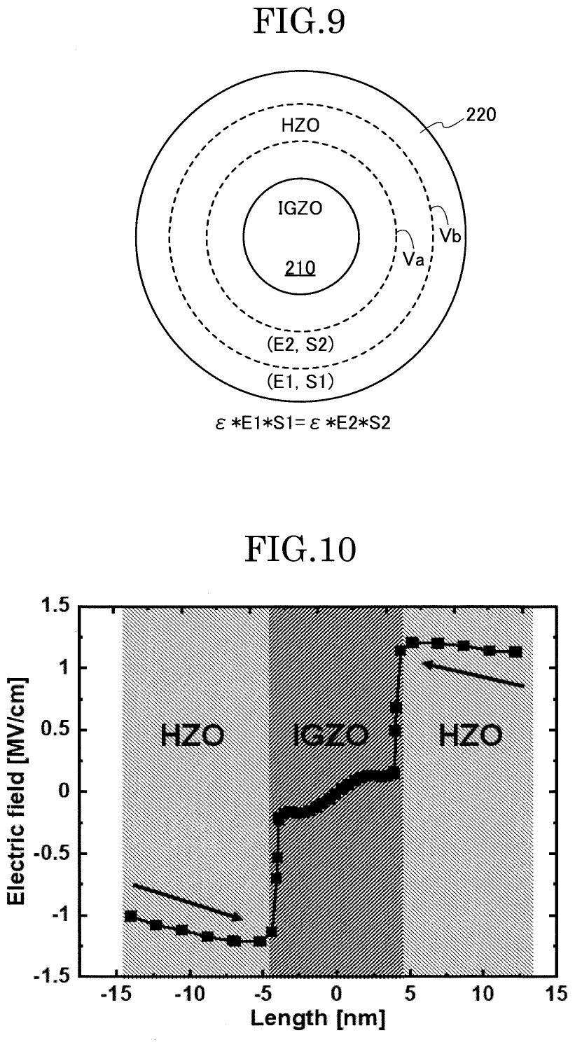

FIG. 9 is a diagram showing a simulation model of an electric field distribution inside the gate insulating layer 220 in the non-volatile memory element 20 according to the embodiment of the present invention. Specifically, FIG. 9 shows an electric field distribution in a plane perpendicular to the longitudinal direction of the semiconductor member 210 and the gate insulating layer 220 shown in FIG. 3. FIG. 10 is a diagram showing a simulation result of the electric field distribution inside the gate insulating layer 220 in the non-volatile memory element 20 according to an embodiment of the present invention. FIG. 10 shows an electric field distribution on a straight line passing through a center point of a cross section perpendicular to the longitudinal direction of the semiconductor member 210 and the gate insulating layer 220 shown in FIG. 3.

In FIG. 9, the dotted lines schematically represent equipotential lines Va and Vb, respectively. Approximately, for the equipotential lines Va and Vb, it is considered that the same magnitude relationship as the ε*E1*S1=ε*E2*S2 is established by the Gaussian theorem. Here, ε, E, and S represent a dielectric constant, an electric field strength, and a surface area, respectively. That is, the electric field strength inside the gate insulating layer 220 increases as it approaches the semiconductor member 210. FIG. 10 shows a state in which the electric field strength in the gate insulating layer 220 (an area marked as H₂O) becomes larger as it approaches the semiconductor member 210 (an area marked as IGZO). In the gate insulating layer 220, a large electric field is formed in a vicinity of the semiconductor member 210 functioning as a channel. Therefore, as shown in FIG. 7, it is considered that inversion of spontaneous polarization occurs continuously along the channel.

As described above, the non-volatile memory element 20 of the present embodiment has a structure in which a periphery of the columnar semiconductor member 210 is surrounded by the cylindrical gate insulating layer 220, and thus has an advantage that spontaneous polarization inversion is likely to occur in the gate insulating layer 220 in the vicinity of the channel. That is, in the present embodiment, it is possible to improve the characteristics of the program operation (particularly, the erase operation) by using the fact that the electric field in the vicinity of the channel is strengthened by the electric field concentration in the three-dimensional structure.

Next, a dependence of the non-volatile memory element 20 of the present embodiment on the diameter of the semiconductor member 210 will be described.

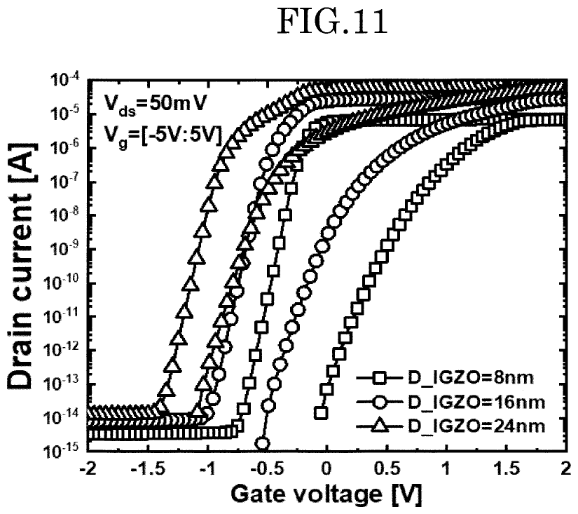

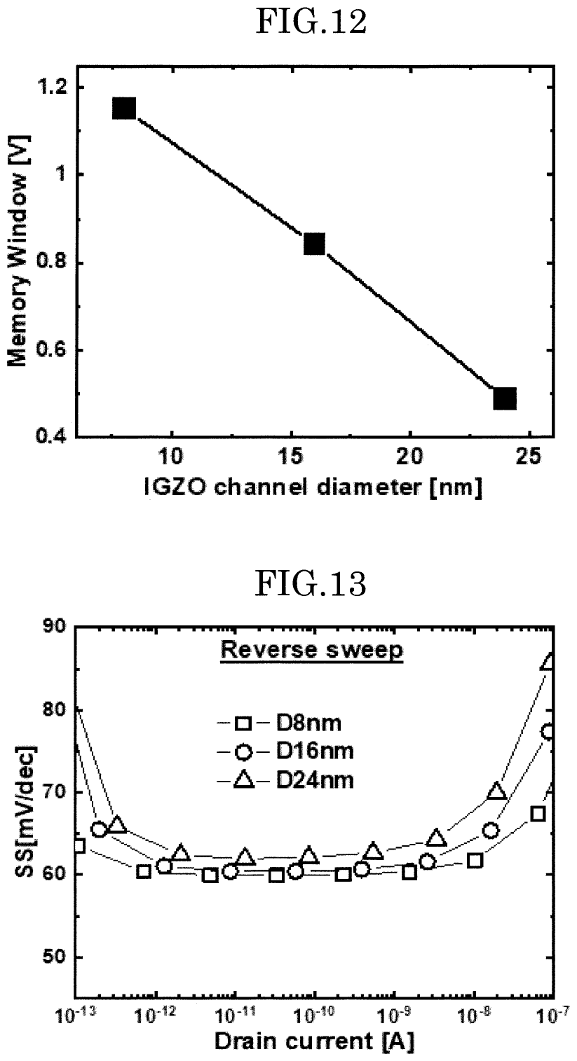

FIG. 11 is a graph showing simulated Id-Vg characteristics of the non-volatile memory element 20 according to an embodiment of the present invention. Specifically, FIG. 11 shows a dependency of Id-Vg characteristics on the diameter of the semiconductor member 210 in FeFET having the structure shown in FIG. 2 and FIG. 3. FIG. 12 is a graph showing a relationship between a width of a memory window and a diameter of the semiconductor member 210 obtained from the Id-Vg characteristics shown in FIG. 11. FIG. 13 is a graph showing relationships between an SS value and a drain current obtained from the Id-Vg characteristics shown in FIG. 11.

In the Id-Vg characteristics shown in FIG. 11, the diameters (D) of the semiconductor member 210 were set to 8 nm, 16 nm or 24 nm, respectively. In FIG. 11, a channel length of the semiconductor member 210 and a thickness of the gate insulating layer 220 were set to 50 nm and 10 nm, respectively. Residual polarization (Pr) was set at 20 μC/cm². The source-drain voltage (Vds) was set to 50 mV, and the gate voltage (Vg) was swept from −5 V to 5 V.

According to the simulation results shown in FIG. 11, the width of the memory window increases as the diameter (D) of the semiconductor member 210, that is, the diameter of the channel decreases. As shown in FIG. 12, the diameter of the semiconductor member 210 and the width of the memory window in the non-volatile memory element 20 have a linear relationship. Referring to FIG. 12, for example, if the diameter of the semiconductor member 210 has a diameter of 20 nm or less, a width of the memory window of 0.6 V or more can be secured. In addition, if the diameter of the semiconductor member 210 is set to be 16 nm or less, a width of the memory window of 0.8 V or more can be secured. Further, if the diameter of the semiconductor member 210 is set to be 10 nm or less, a width of the memory window of 1.0 V or more can be secured.

Further, as shown in FIG. 13, the SS value of the non-volatile memory element 20 is not dependent on the diameter of the semiconductor member 210 and falls within the range of 60 mV/dec or more and 65 mV/dec or less. In addition, it was found that the SS value of the non-volatile memory element 20 decreases as the diameter of the semiconductor member 210 decreases. From the above, it was found that the SS value of the non-volatile memory element 20 is a good value regardless of the diameter of the semiconductor member 210.

As described above, as shown in FIG. 2 and FIG. 3, the non-volatile memory element 20 of the present embodiment has a structure in which the inside of the cylindrical gate insulating layer 220 is occupied by the semiconductor member 210. By adopting such a configuration, the non-volatile memory element 20 can obtain the good width of the memory window and the SS value, for example, in the case where the diameter (D) of the semiconductor member 210 is 20 nm or less and the channel length (L) is 1 μm or less.

### Element Structure of Comparative Example 2

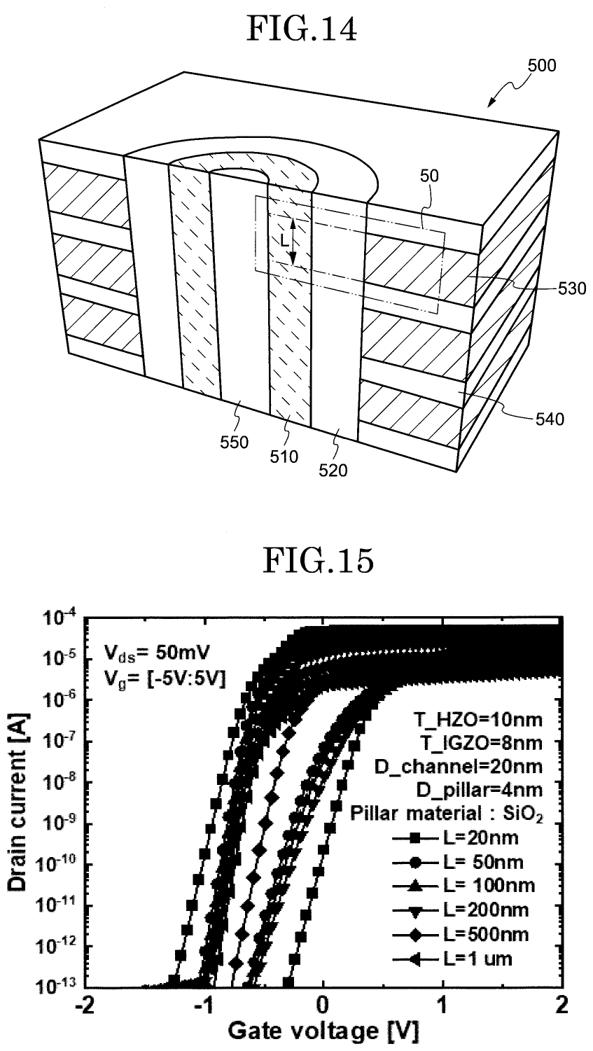

FIG. 14 is a cross-sectional perspective view showing the element structure of a non-volatile memory device 500 of comparative example 2. As shown in FIG. 14, the non-volatile memory device 500 has a three-dimensional stacked structure in which a plurality of non-volatile memory elements 50 is three-dimensionally integrated. The plurality of non-volatile storage elements 50 is arranged in series along the longitudinal direction of a channel layer 510 in common with the cylindrical channel layer 510 functioning as a channel. The non-volatile memory device 50 is a FeFET including the channel layer 510, a gate insulating layer 520, and a gate electrode 530. The channel layer 510 and the gate insulating layer 520 are common to the plurality of non-volatile memory elements 50. A difference between the non-volatile memory element 20 of the present embodiment and the non-volatile memory element 50 shown in FIG. 14 is that the non-volatile memory element 50 has a cylindrical shape in the channel layer 510 and has a filler member 550 made of an insulating material inside the channel layer 510. The filler member 550 functions as a filling member that fills the inside of the cylindrical channel layer 510. As the filler member 550, an insulating material such as silicon oxide, silicon nitride, or resin can be used. In the present embodiment, a member with a diameter of 4 nm made of silicon oxide is used as the filler member 550.

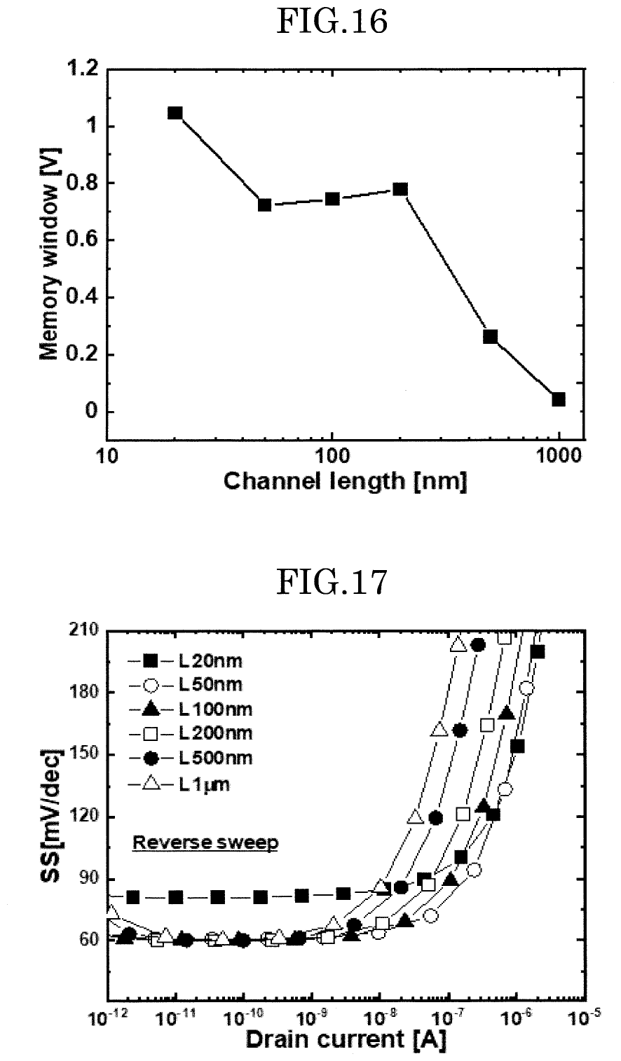

FIG. 15 is a graph showing simulated Id-Vg characteristics of the non-volatile memory device 50 of comparative example 2. Specifically, FIG. 15 shows a dependence of Id-Vg characteristics on the channel length in FeFET having the configuration shown in FIG. 14. FIG. 16 is a graph showing a relationship between a width of a memory window and a channel length obtained from Id-Vg characteristics shown in FIG. 15. FIG. 17 is a graph showing relationships between an SS value and a drain current obtained from Id-Vg characteristics shown in FIG. 15.

In Id-Vg characteristics shown in FIG. 15, a channel length (L) of the channel layer 510 was set to 20 nm, 50 nm, 100 nm, 200 nm, 500 nm or 1 μm, respectively. In FIG. 15, a thickness of the channel layer 510 and a thickness of the gate insulating layer 520 were set to 8 nm and 10 nm, respectively. Residual polarization (Pr) was set at 20 μC/cm². The source-drain voltage (Vds) was set to 50 mV and the gate voltage (Vg) was swept from −5 V to 5 V.

According to the simulations shown in FIG. 15 and FIG. 16, it is found that the memory window gradually opens in a range in which the channel length is 500 nm or less, and the width of the memory window increases as the channel length decreases. Particularly, in a range in which the channel length is 50 nm or more and 200 nm or less, the width of the memory window is stable in a range in which the width is about 0.7 V or more and 0.8 V or less. On the other hand, if the channel length is 50 nm or less, the width of the memory window is increased. As a factor of this, the influence of the coupling between the source-side potential and the drain-side potential is considered.

Further, as shown in FIG. 17, it was found that SS values of the non-volatile memory device 50 of comparative example 2 did not depend on the channel length, but remained substantially around 60 mV/dec. On the other hand, in the case where the channel length is 20 nm, a slight degradation in SS values is confirmed. In view of these facts, it is considered that if the channel length of the non-volatile memory device 50 is less than 50 nm, the coupling between the source-side potential and the drain-side potential causes a property degradation such as a so-called short channel effect.

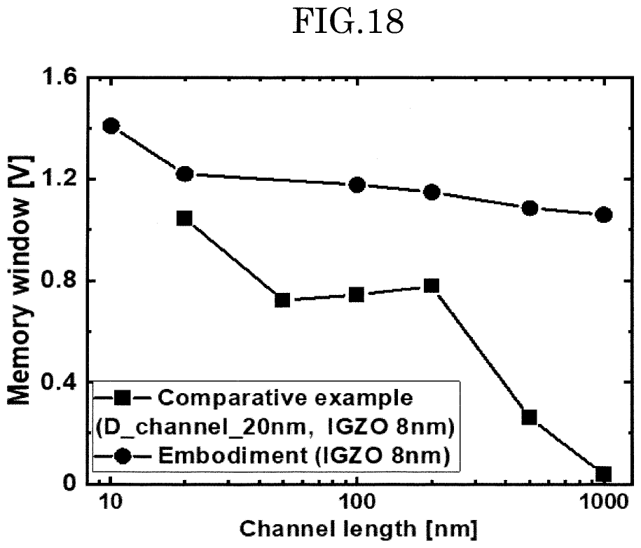

FIG. 18 is a graph comparing a dependence of the width of the memory window on the channel length of the non-volatile memory element 20 of an embodiment of the present invention and that of the non-volatile memory element 50 of comparative example 2. In FIG. 18, a plot represented by “Embodiment” indicates a width of the memory window of the non-volatile memory element 20 of the present embodiment. A plot represented by “Comparative example” indicates the width of the memory window of the non-volatile memory device 50 of comparative example 2. For “Comparative example”, the expression “D_channel_20 nm” means a configuration in which a cylindrical IGZO having an 8 nm film thickness is provided around the filler member with a diameter of 4 nm.

As shown in FIG. 18, in a range in which the channel length is 1 μm or less, the width of the memory window of the non-volatile memory element 20 of the embodiment of the present invention is larger than the width of the memory window of the non-volatile memory element 50 of comparative example 2. As described above, the non-volatile memory elements 20 of the present embodiment can stably secure a larger memory window than the non-volatile memory element 50 of comparative example 2 regardless of the channel length. That is, the non-volatile memory element 20 of the present embodiment can significantly improve the memory window as compared with the non-volatile memory element 50 of comparative example 2.

### Modification 1

In this modification, a relationship between an outer diameter of the semiconductor member 210 and a film thickness of the gate insulating layer 220 will be described.

FIG. 19 is a cross-sectional perspective view showing a modification of an element structure of the non-volatile memory device 100 according to an embodiment of the present invention. Specifically, FIG. 19 corresponds to an enlarged view of a portion surrounded by the grid line 200 in the non-volatile memory device 100 shown in FIG. 1.

In the embodiment shown in FIG. 19, a thickness D2 of the gate insulating layer 220 made of ferroelectric material is larger than an outer diameter D1 of the semiconductor member 210 (that is, the diameter of the semiconductor member 210). Specifically, if the outer diameter of the semiconductor member 210 is D1 and the thickness of the gate insulating layer 220 is D2, D2 is made equal to or larger than D1. Such relationships are derived from the simulation results described below.

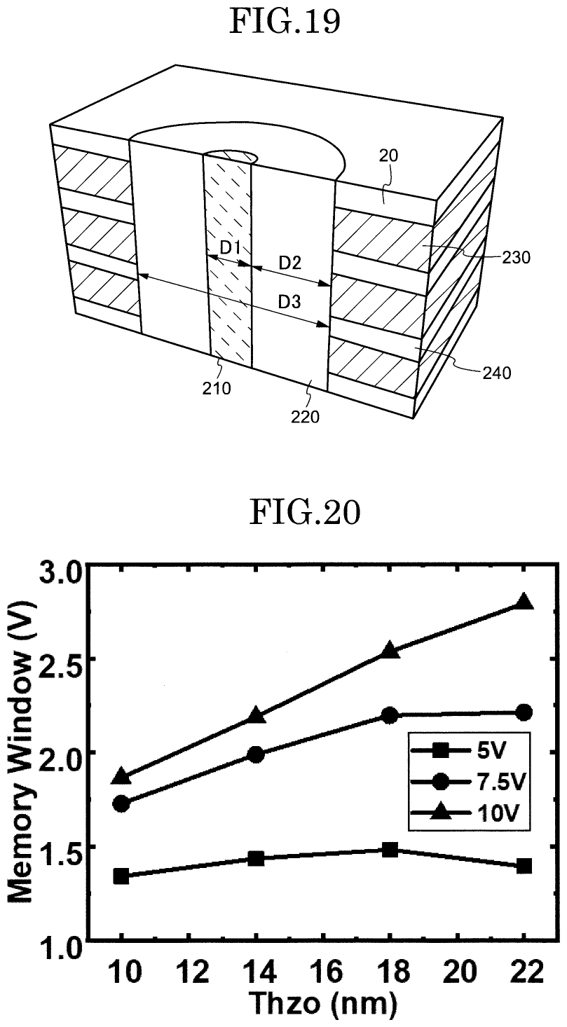

FIG. 20 is a graph showing a relationship between a width of the memory window and a thickness of the gate insulating layer 220 (referred to as “Thzo” in FIG. 20) in the non-volatile memory element of the element structure shown in FIG. 19. In FIG. 20, a channel length and a diameter of the semiconductor member 210 were set to 50 nm and 8 nm, respectively. Write voltages were 5 V, 7.5 V, and 10 V.

As shown in FIG. 20, in a range in which the film thickness D2 of the gate insulating layer 220 is 10 nm or more and 18 nm or less, the width of the memory window gradually increases as the film thickness D2 of the gate insulating layer 220 increases regardless of the write voltage. On the other hand, if the film thickness D2 of the gate insulating layer 220 exceeds 18 nm, the width of the memory window decreases in the case where the write voltage is 5 V, and the width of the memory window hardly changes in the case where the write voltage is 7.5 V.

In the case where the write voltage is 5 V, a tendency observed in the case where the film thickness D2 of the gate insulating layer 220 exceeds 18 nm is considered to be due to insufficient write voltage applied to the non-volatile memory device due to the increased film thickness of the gate insulating layer 220. Therefore, in the case where the write voltage is 10 V, the width of the memory window is increased even if the film thickness D2 of the gate insulating layer 220 exceeds 18 nm. That is, it is considered that as the write voltage is increased, the thickness of the gate insulating layer 220 at which the memory window reaches the maximum is increased. However, since an increase in the write voltage causes an increase in the power consumed by the non-volatile memory device 100, it is desirable that the write voltage be 7.5 V or less.

As described above, in the case where the write voltage is 7.5 V or less, it has been confirmed that, in a range in which the film thickness D2 of the gate insulating layer 220 is at least 10 nm or more and 18 nm or less, the width of the memory window linearly increases regardless of the write voltage, and a memory window having a width at least of 1.3 V or more can be secured. It should be noted that, according to FIG. 20, if the respective graphs are extrapolated to a range in which the film thickness D2 is 10 nm or less, it is expected that at least in a range in which the film thickness D2 of the gate insulating layer 220 is 8 nm or more, a memory window having a width of 1.3 V or more can be secured.

In the case where the thickness D2 of the gate insulating layer 220 is equal to or larger than the outer diameter D1 (here, 8 nm) of the semiconductor member 210, it can be said that a sufficiently wide memory window can be secured. More preferably, the thickness D2 of the gate insulating layer 220 is 1.4 times the outer diameter D1 of the semiconductor member 210 or more. That is, in the case of the exemplary embodiment shown in FIG. 20, the thickness D2 of the gate insulating layer 220 is preferably 8 nm or more (preferably 12 nm or more, more preferably 16 nm or more).

As described above, in the element structure shown in FIG. 19, the thickness D2 of the gate insulating layer 220 is made equal to the outer diameter D1 of the semiconductor member 210 or is made larger than the outer diameter D1 of the semiconductor member 210.

The element structure shown in this modification is particularly useful in the case where the diameter of a memory hole (a cylindrical hole with a diameter D3 in FIG. 19) is about 50 nm. As described with reference to FIG. 12, in the element structure shown in FIG. 2 that does not substantially include a hollow portion or other member, the smaller the outer diameter of the semiconductor member 210, the better the width of the memory window is obtained. However, in the case where a diameter of the memory hole is large, the outer diameter of the semiconductor member 210 inevitably increases, which is not desirable from the viewpoint of securing the memory window. On the other hand, in the element structure of the present modification, by increasing the thickness D2 of the gate insulating layer 220 while reducing the outer diameter D1 of the semiconductor member 210, it is possible to sufficiently cope with a memory hole having a diameter of 50 nm while securing a memory window having a sufficient width. Specifically, assuming that the diameter of the memory hole is 30 nm or more and 60 nm or less, the outer diameter of the semiconductor member 210 is preferably 1 nm or more and 12 nm or less, and the thickness of the gate insulating layer 220 is preferably 15 nm or more and 22 nm or less.

### Modification 2

In the present modification, an example in which a hollow portion having a diameter sufficiently smaller than an outer diameter of the semiconductor member is present in the center of the semiconductor member will be described.

FIG. 21 is a cross-sectional perspective view showing a modification of the element structure of the non-volatile memory device 100 according to the embodiment of the present invention. Specifically, FIG. 21 corresponds to an enlarged view of a portion surrounded by the grid line 200 in the non-volatile memory device 100 shown in FIG. 1.

In the embodiment shown in FIG. 21, a semiconductor member 210a has a cylindrical shape. In other words, the semiconductor member 210a has a hollow part at the center. In this modification, the hollow part of the semiconductor member 210a is filled with a filler member 250a made of an insulating material. However, the present invention is not limited to this embodiment, and the hollow portion of the semiconductor member 210a may be any void. At this time, in the present modification, an inner diameter D5 of the semiconductor member 210a (that is, a diameter of the filler member 250a) is sufficiently smaller than the outer diameter D1 of the semiconductor member 210a. Specifically, a ratio of the inner diameter D5 of the semiconductor member 210a to the outer diameter D1 of the semiconductor member 210a is 15% or less (preferably 10% or less). Such relationships are derived from the simulation results described below.

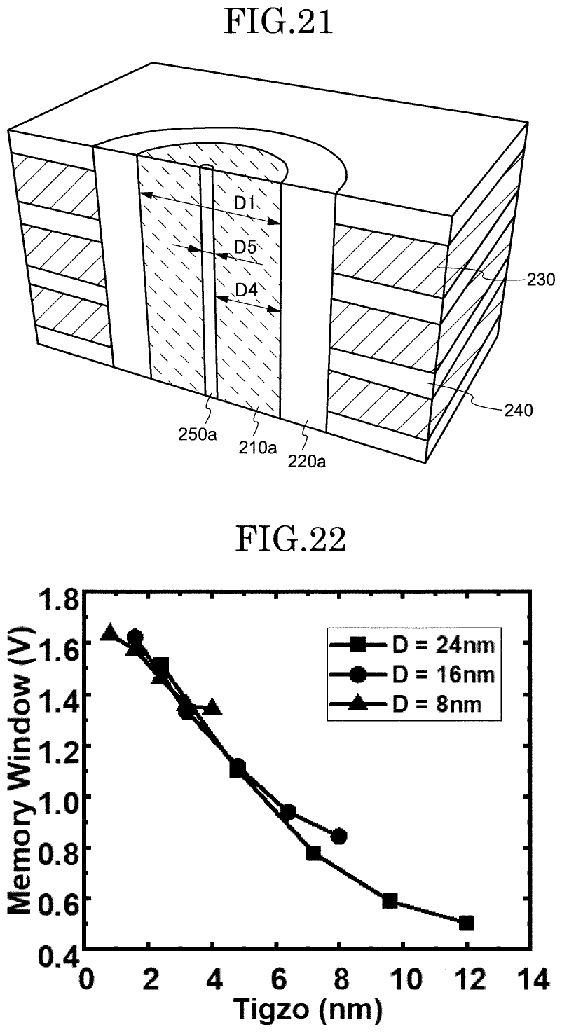

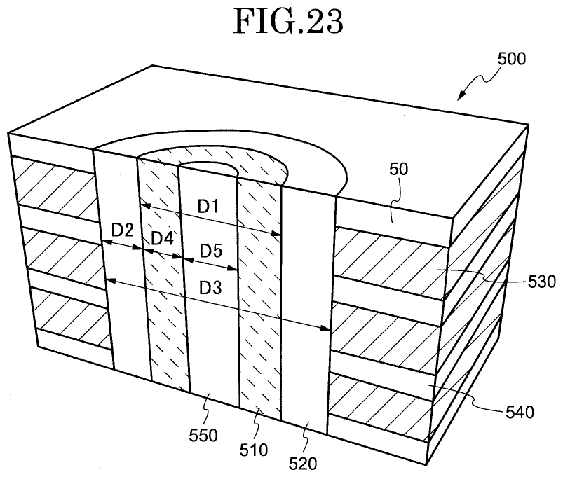

FIG. 22 is a graph showing a relationship between a width of a memory window and a film thickness D4 of a semiconductor member (referred to as “Tigzo” in FIG. 22) in the non-volatile memory element of the element structure shown in FIG. 21. Here, the film thickness of the semiconductor member corresponds to a distance between the filler member 250a and a gate insulating layer 220a in FIG. 21. That is, in the embodiment shown in FIG. 21, a relationship of D1=2×D4+D5 is established. In FIG. 22, a channel length of the semiconductor member was set to 50 nm, the thickness of the gate insulating layer was set to 10 nm, and the write voltage was set to 5 V. Further, the outer diameters D1 of the semiconductor member (referred to simply as “D” in FIG. 22) are 8 nm, 16 nm and 24 nm.

In the respective curves shown in FIG. 22, the rightmost plot (the plot having the largest Tigzo) corresponds to the element structure in which the semiconductor member has no hollow part, that is, the element structure shown in FIG. 2. For example, in the case of a plot corresponding to D1=24 nm, the film thickness D4 (Tigzo) in the rightmost plot is 12 nm and corresponds to the radius of the semiconductor member without hollows (D5=0). On the other hand, all the plots other than the plots located at the right end correspond to the element structure in which D5>0 is established in the semiconductor member as shown in FIG. 21.

According to the result shown in FIG. 22, in each curve, in the vicinity of the plot located at the right end, the rate of change in the width of the memory window with respect to the change in the film thickness (Tigzo) of the semiconductor member is small. For example, in the case of the curve corresponding to D1=8 nm, the widths (approximately 1.35 V) of the memory windows are substantially the same between the rightmost plot (Tigzo=4 nm) and the neighboring plot (Tigzo=3 nm). This indicates that, in the case of D1=8 nm, there is little change between the width of the memory window in the element structure having the semiconductor member without the hollow portion (the element structure shown in FIG. 2) and the width of the memory window in the element structure including the semiconductor member having 2 nm hollow portion (that is, the element structure shown in FIG. 21).

As described above, in the case of D1=8 nm, in element structure shown in FIG. 21, in the case where the volume of the hollow portion is sufficiently small, the width of the memory window substantially equivalent to that of the element structure shown in FIG. 2 can be secured. From this, it can be said that the element structure having the semiconductor member having the hollow portion having the outer diameter D5 of 2 nm or less (preferably 1 nm or less) can ensure the width of the memory window substantially equivalent to the element structure having the semiconductor member having no hollow portion (D5=0). For example, in the case of D1=16 nm, the width of the memory window in the case where Tigzo=7 nm (for example, the outer diameter of the hollows is 2 nm) is about 0.9 V and does not differ substantially from the width of the memory window (about 0.85 V) in the rightmost plot. Also, in the case of D=24 nm, the width of the memory window in the case where Tigzo=11 nm (for example, the outer diameter of the hollow part is 2 nm) is about 0.55 V, and there is no substantial difference from the width of the memory window (about 0.5 V) in the rightmost plot.

From the above results, if the ratio of the inner diameter D5 of the semiconductor member to the outer diameter D1 of the semiconductor member is 15% or less (preferably, 10% or less), the device structure shown in FIG. 21 can achieve a width of the memory window practically equivalent to the device structure including a semiconductor member without a hollow portion shown in FIG. 2, and that there are no practical problems.

The above results mean that the process margin of the element structure shown in FIG. 2 is high. For example, in the case of the element structure shown in FIG. 2, the semiconductor member 210 is formed by filling holes (trenches) having diameters of about 30 to 50 nm with a metal oxide material. At this time, a gap that cannot be filled in the vicinity of the center of the semiconductor member 210 may be formed because filling proceeds from the inner wall of the trench. However, even in this case, if the volume of the void is sufficiently small, the memory window is considered to be substantially equivalent to that without the void.

Incidentally, in FIG. 22, for example, in the case where D=16 nm, and Tigzo=4 nm, the width of the memory window is about 1.25 V. Since the thickness of the gate insulating layer is 10 nm in this case, the diameter of the memory hole (cylindrical holes having D3 of FIG. 23 as the diameter) is 36 nm. Such an element structure corresponds to the element structure of comparative example 2 shown in FIG. 14. Specifically, referring to FIG. 23, an outer diameter D1 of a semiconductor member 510 is 16 nm, the film thickness D2 of the gate insulating layer 520 is 10 nm, the diameter D3 of the memory hole is 36 nm, the film thickness D4 of the semiconductor member 510 is 4 nm, and the outer diameter D5 of the filler member 550 is 8 nm.

In contrast, in FIG. 19, in the element structure in which the film thickness of the semiconductor member 210 (corresponding to half of the outer diameter D1 of the semiconductor member 210) and the diameter D3 of the memory hole are the same as the element structure shown in FIG. 23, the outer diameter D1 of the semiconductor member 210 is 8 nm, the film thickness D2 of the gate insulating layer 220 is 14 nm, and the diameter D3 of the memory hole is 36 nm. The width of the memory window of such an element structure is approximately 1.45 V according to the result shown in FIG. 20. That is, it is larger than the width (approximately 1.25 V) of the memory window in the element structure shown in FIG. 23.

From the above, in the case where the ratio of the sum of the film thicknesses of the semiconductor member (which is D1 in the case of the element structure shown in FIG. 19 and twice as much as D4 in the case of the element structure shown in FIG. 23) to the diameter D3 of the memory hole is compared under the same condition, it can be said that the width of the memory window is larger in the element structure shown in FIG. 19 than in the element structure shown in FIG. 23.

What a person skilled in the art appropriately adds, deletes, or changes the design of the constituent elements, or adds, omits, or changes the conditions of the steps, based on the non-volatile memory device which is an embodiment of the present invention, is also included in the scope of the present invention as long as it has the gist of the present invention. In addition, each of the above embodiments (including modifications) can be combined with each other as long as no contradictions arise.

In addition, it is to be understood that the present invention provides other operational effects that are different from the operational effects provided by the aspects of the above-described embodiments, and those that are obvious from the description of the present specification or those that can be easily predicted by a person skilled in the art.

What is claimed is:

1. A ferroelectric memory device having a three-dimensional stacked structure with multiple ferroelectric memory elements arranged in series, the ferroelectric memory device comprising:
a semiconductor member having a columnar shape including a metal oxide;
a ferroelectric layer containing hafnium oxide and surrounding the semiconductor member in contact with a side surface of the semiconductor member; and
a plurality of gate electrodes arranged along a longitudinal direction of the semiconductor member and facing a side of the semiconductor member through the ferroelectric layer, wherein
the semiconductor member is a continuous member from its outer periphery to its central axis.

2. The ferroelectric memory device according to claim 1, wherein the multiple ferroelectric memory elements share the same semiconductor member.

3. The ferroelectric memory device according to claim 1, wherein a diameter of the semiconductor member is 20 nm or less.

4. The ferroelectric memory device according to claim 1, wherein the metal oxide is an oxide comprising one or more metals selected from a group consisting of In, Ga, Zn, and Sn.

5. The ferroelectric memory device according to claim 1, wherein the metal oxide is IGZO, ITO, IZO, or ITZO.

6. The ferroelectric memory device according to claim 1 further comprising:
a plurality of insulating layers provided between each of the plurality of gate electrodes.

7. The ferroelectric memory device according to claim 1, wherein a width of each of the plurality of gate electrodes is 1 μm or less.

8. The ferroelectric memory device according to claim 1, wherein a thickness of the ferroelectric layer is 5 nm or more and 22 nm or less.

9. The ferroelectric memory device according to claim 1, wherein a thickness of the ferroelectric layer is greater than or equal to an outer diameter of the semiconductor member.

10. A ferroelectric memory device having a three-dimensional stacked structure with multiple ferroelectric memory elements arranged in series, the ferroelectric memory device comprising:
a semiconductor member having a cylindrical shape including a metal oxide;
a ferroelectric layer containing hafnium oxide and surrounding the semiconductor member in contact with a side surface of the semiconductor member; and
a plurality of gate electrodes arranged along a longitudinal direction of the semiconductor member and facing a side of the semiconductor member through the ferroelectric layer, wherein
a ratio of an inner diameter of the semiconductor member to an outer diameter of the semiconductor member is 15% or less.

11. The ferroelectric memory device according to claim 10, wherein the multiple ferroelectric memory elements share the same semiconductor member.

12. The ferroelectric memory device according to claim 10, wherein a diameter of the semiconductor member is 20 nm or less.

13. The ferroelectric memory device according to claim 10, wherein the metal oxide is an oxide comprising one or more metals selected from a group consisting of In, Ga, Zn, and Sn.

14. The ferroelectric memory device according to claim 10, wherein the metal oxide is IGZO, ITO, IZO, or ITZO.

15. The ferroelectric memory device according to claim 10 further comprising:
a plurality of insulating layers provided between each of the plurality of gate electrodes.

16. The ferroelectric memory device according to claim 10, wherein a width of each of the plurality of gate electrodes is 1 μm or less.

17. The ferroelectric memory device according to claim 10, wherein a thickness of the ferroelectric layer is 5 nm or more and 22 nm or less.

18. The ferroelectric memory device according to claim 10, wherein a thickness of the ferroelectric layer is greater than or equal to an outer diameter of the semiconductor member.
